(19) United States
(12) Patent Application Publication
(10) Pub. No.: US 2024/0146268 A1
(43) Pub. Date: May 2, 2024

(54) REDUCTION OF NOISE AND WEAK AVALANCHE CURRENT INDUCED ERRORS IN BIPOLAR AMPLIFIERS

(71) Applicant: TEXAS INSTRUMENTS INCORPORATED, Dallas, TX (US)

(72) Inventors: Tyler James Archer, VAIL, AZ (US); Bharath Karthik Vasan, TUCSON, AZ (US); Jerry L. Doorenbos, TUCSON, AZ (US)

(21) Appl. No.: 17/977,435

(22) Filed: Oct. 31, 2022

(51) Int. Cl. H03F 3/45

(52) U.S. Cl. CPC H03F 3/456; H03F 3/45174; H03F 2200/372

(57) ABSTRACT

Examples of circuits and amplifiers include recirculation circuitry to reduce or cancel error currents produced by target bipolar junction transistors (BJTs). In an example, first recirculation circuitry is coupled to the base of a first signal-conveyance BJT and to one of the collector or the emitter of the first signal-conveyance BJT; second recirculation circuitry is coupled to the base of a second signal-conveyance BJT and to one of the collector or the emitter of the second signal-conveyance BJT; and biasing circuitry is coupled to the first and second recirculation circuitry. The recirculation circuitry may be implemented with BJTs or MOSFETs. Configurations are provided in which error current(s) are recirculated between the base and collector/emitter node of each target BJT.

### FIELD OF DISCLOSURE

This disclosure relates generally to reduction or cancelation of 1/f noise and weak avalanche breakdown currents in bipolar amplifiers, and more particularly to reduction or cancelation of 1/f noise currents produced by base-emitter junctions of bipolar junction transistors (BJTs) and reduction or cancelation of weak avalanche breakdown currents produced by collector-base junctions of BJTs, where f is the frequency of the output signal.

### BACKGROUND

In bipolar amplifiers, signal-path BJTs produce 1/f noise currents in their base-emitter junctions and weak avalanche breakdown currents in their collector-base junctions. When these error currents are introduced into the signal path, undesirable loss of signal fidelity and degradation of amplifier performance metrics results. The loss of signal fidelity due to 1/f noise currents is particularly acute in low-frequency applications such as audio. The degradation of performance metrics due to weak avalanche breakdown currents is particularly noticeable in high-voltage applications in which large collector-base voltages are present.

Some conventional solutions to reduce 1/f noise currents use small bias currents for signal-path BJTs. However, this results in bandwidth and slew rate limitations. In an attempt to avoid slew rate limitations while reducing 1/f noise, other conventional solutions use dynamically-biased amplifier stages, such as those having cross-coupled architectures, that allow large gₘ block bias currents to be used for low flat-band noise while having small dynamically-boosted bias currents for signal-path BJTs elsewhere in the stage. However, these architectures can multiply the effects of 1/f noise on the signal, reducing the benefits of having small bias currents, and can also increase signal error resulting from weak avalanche breakdown currents. Still other conventional solutions use cascode transistors to limit collector-base voltages present at high supply voltages, reducing weak avalanche breakdown current. However, this limits output signal swing and consumes additional die area.

A better solution to these issues is desirable, and in this context embodiments of the invention arise.

### SUMMARY

In accordance with an example, a circuit comprises a target bipolar junction transistor (BJT) having an emitter, a collector and a base; and recirculation circuitry coupled to the base of the target BJT and to one of the collector or the emitter of the target BJT. The recirculation circuitry is configured to form a recirculation path for at least one error current produced by the target BJT.

In accordance with an example, an amplifier comprises first and second signal-conveyance BJTs; a first branch coupled to the emitter of the first signal-conveyance BJT and to a first input current path; a second branch coupled to the emitter of the second signal-conveyance BJT and to a second input current path; first recirculation circuitry coupled to the base of the first signal-conveyance BJT and to one of the collector or the emitter of the first signal-conveyance BJT; second recirculation circuitry coupled to the base of the second signal-conveyance BJT and to one of the collector or the emitter of the second signal-conveyance BJT; and biasing circuitry coupled to the first and second recirculation circuitry.

In accordance with an example, an amplifier comprises n target BJTs; n instances of recirculation circuitry; and biasing circuitry coupled to the n instances of recirculation circuitry. Each of the n instances of recirculation circuitry includes a recirculation transistor and is coupled to the base of a corresponding target BJT and to one of the collector or the emitter of the corresponding target BJT. The biasing circuitry is configured to activate the n recirculation transistors to form n recirculation paths for the n target BJTs, respectively, to isolate at least one error current produced by each of the n target BJTs.

These and other features will be better understood from the following detailed description with reference to the accompanying drawings.

### BRIEF DESCRIPTION OF THE DRAWINGS

Features of the disclosure may be understood from the following figures taken in conjunction with the detailed description.

FIG. 1A is a circuit diagram of a stage of an example amplifier with a first configuration of example recirculation circuitry implemented with bipolar junction transistors (BJTs).

FIG. 1B is a circuit diagram of a stage of an example amplifier with the first configuration of example recirculation circuitry implemented with metal-oxide-silicon field-effect transistors (MOSFETs).

FIG. 2A is a circuit diagram of a stage of an example amplifier with a second configuration of recirculation circuitry implemented with BJTs.

FIG. 2B is a circuit diagram of a stage of an example amplifier with the second configuration of recirculation circuitry implemented with MOSFETs.

FIG. 3 is a circuit diagram of a stage of an example amplifier, in which the stage has a cross-coupled architecture as well as example recirculation circuitry.

FIG. 4A is a circuit diagram of a Wilson current mirror, and FIG. 4B is a circuit diagram of a Wilson current mirror incorporating example recirculation circuitry.

FIG. 5 is a circuit diagram of an example current mirror with example recirculation circuitry.

FIG. 6 is a flow diagram of an example method of operating example recirculation circuitry with respect to signal-conveyance BJTs in a stage of an example amplifier.

### DETAILED DESCRIPTION

Specific examples are described below in detail with reference to the accompanying figures. These examples are not intended to be limiting. In the drawings, corresponding numerals and symbols generally refer to corresponding parts unless otherwise indicated. The objects depicted in the drawings are not necessarily drawn to scale.

Example circuits, amplifiers and systems are provided that significantly reduce or cancel error currents, such as 1/f noise and weak avalanche breakdown currents, from targeted error-current-producing BJTs, eliminating the impact of such currents on signal fidelity, rather than merely mitigating performance degradation using small bias currents for lower 1/f noise, or using cascodes to limit collector-base voltages to lower weak avalanche breakdown current. In examples, recirculation circuitry is implemented for each targeted error-current-producing BJT to form a recirculation path to reduce and isolate the 1/f noise current and/or weak avalanche breakdown current (avalanche current) produced by that BJT. Each recirculation transistor associated with a targeted error-current-producing BJT is configured to convey the error current(s) to circuit node(s) through which the effects of the error current(s) are canceled. Biasing circuitry may be included to bias the recirculation circuitry.

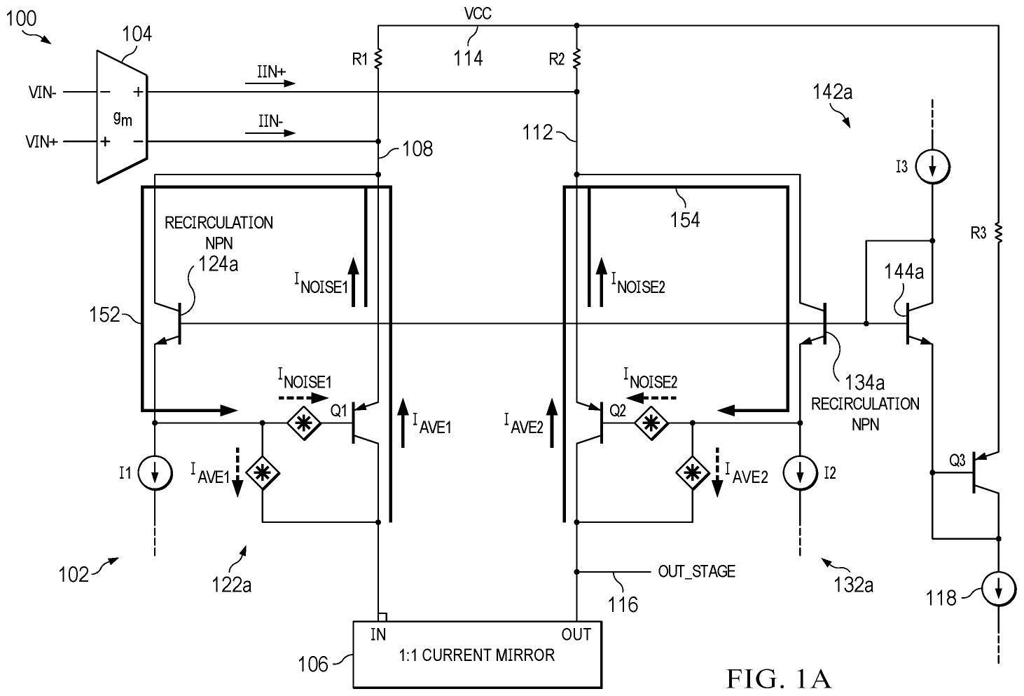

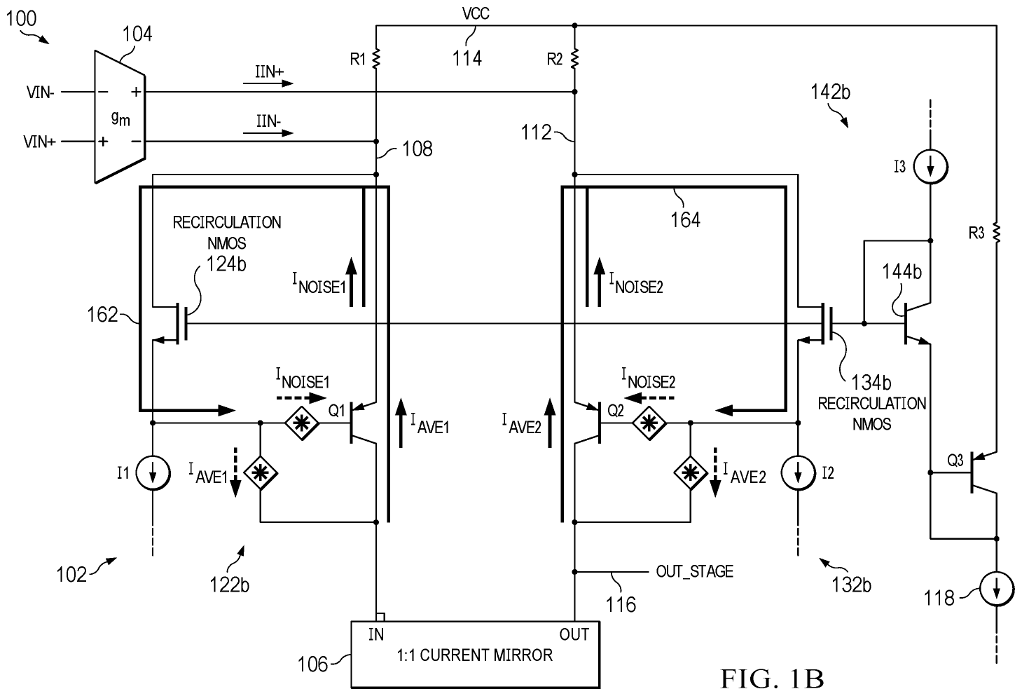

FIG. 1A is a circuit diagram of a stage (or portion) 102 of an example amplifier 100. Stage 102 includes a core that comprises a pair of signal-conveyance BJTs Q1 and Q2, a voltage-to-current (VI) converter 104, another BJT Q3, a current mirror 106, and resistors R1, R2 and R3. In the illustrated example, each of BJTs Q1, Q2 and Q3 is a PNP transistor. The input/output ratio of the currents of current mirror 106 may be set according to the application of amplifier 100. In the illustrated example, the ratio is 1:1. Each of resistors R1, R2 and R3 has a resistance that is suitable for the particular application of amplifier 100. The respective resistances of these resistors may vary depending on the application.

In operation, VI converter 104 converts an input voltage signal to an output current signal. To that end, VI converter 104 has a pair of inputs at which voltage signal components VIN+ and VIN− of a differential voltage signal are input, and respective outputs at which current signal components IN+ and IN− of a differential current signal are output. The output from which current signal component IN− flows is coupled to a first branch 108 of stage 102, and the output from which current signal component IN+ flows is coupled to a second branch 112 of stage 102. First branch 108 includes resistor R1 which is coupled between a supply voltage terminal 114 adapted to be coupled to a positive supply voltage (VCC) and the emitter of BJT Q1. Second branch 112 includes resistor R2 which is coupled between supply voltage terminal 114 and the emitter of BJT Q2. The collectors of Q1 and Q2 are respectively coupled to the input and output of current mirror 106. The coupling between the collector of BJT Q2 and the output of current mirror 106 defines an output node 116 at which an output voltage or current for stage 102 (OUT_STAGE) is output. Resistor R3 is coupled between supply voltage terminal 114 and the emitter of BJT Q3. The base and collector of BJT Q3 are coupled together and to a current source 118 which is also part of the core.

In operation, signal-conveyance BJTs Q1 and Q2 produce error currents, and in particular base-emitter 1/f noise currents and base-collector avalanche currents. The 1/f noise current and the avalanche current produced by BJT Q1 are denoted I_{NOISE1} and I_{AVE1}, respectively. The 1/f noise current and the avalanche current produced by BJT Q2 are denoted I_{NOISE2} and I_{AVE2}, respectively. These error currents are shown schematically on FIG. 1A.

To reduce or cancel these error currents, which occur during normal operation of amplifier 100, stage 102 includes first recirculation circuitry 122a associated with signal-conveyance BJT Q1, and second recirculation circuitry 132a associated with signal-conveyance BJT Q2. First recirculation circuitry 122a includes a first recirculation transistor 124a, which in this example is an NPN-type BJT, and a first fixed current source I1 coupled to the emitter of first recirculation transistor 124a and to the base of Q1. The collector of first recirculation transistor 124a is coupled to the emitter of Q1. Second recirculation circuitry 132a includes a second recirculation transistor 134a, which in this example is an NPN-type BJT, and a second fixed current source 12 coupled to the emitter of second recirculation transistor 134a and to the base of Q2. The collector of second recirculation transistor 134a is coupled to the emitter of Q2.

Biasing circuitry 142a may be included to bias first and second recirculation NPN transistors 124a and 134a. In the example BJT implementation of FIG. 1A, biasing circuitry 142a includes an NPN-type BJT 144a and a fixed current source 13 coupled to the collector and base of NPN transistor 144a. The common collector-base node of NPN transistor 144a is coupled to the bases of recirculation NPN transistors 124a and 134a, and the emitter of NPN transistor 144a is coupled to base and collector of Q3. Biasing circuitry 142a is an example of structure to bias recirculation NPN transistors 124a and 134a. Other suitable structure may be used instead.

In operation, with biasing circuitry 142a activated, first recirculation circuitry 122a creates a first recirculation path 152 in which error currents I_{NOISE1} and I_{AVE1} are combined and isolated. I_{AVE1} flows from the collector to the emitter node of BJT Q1, where it is combined with I_{NOISE1}. These error currents then flow through first recirculation NPN transistor 124a and to the base of BJT Q1 where I_{NOISE1} and I_{AVE1} are isolated. Second recirculation circuitry 132a operates similarly in that it creates a second recirculation path 154 in which error currents I_{NOISE2} and I_{AVE2} are combined and isolated. I_{AVE2} flows from the collector to the emitter node of BJT Q2, where it is combined with I_{NOISE2}. These error currents then flow through second recirculation NPN transistor 134a and to the base of BJT Q2, where I_{NOISE2} and I_{AVE2} are isolated.

In FIG. 1B, the core of stage 102 is the same as that in FIG. 1A, and thus core components are identified by the same reference numerals/symbols used in FIG. 1A. However, in FIG. 1B, the recirculation and biasing circuitry for stage (or portion) 102 of example amplifier 100, and in particular signal-conveying BJTs Q1 and Q2, is implemented with n-type MOSFETs (NMOS transistors), instead of NPN transistors. In FIG. 1B, the first and second recirculation circuitry are identified by reference numerals 122b and 132b, respectively, and the biasing circuitry is identified by reference numeral 142b. First recirculation circuitry 122b includes first recirculation NMOS transistor 124b and fixed current source I1, second recirculation circuitry 132b includes second recirculation NMOS transistor 134b and fixed current source 12, and biasing circuitry 142b includes NMOS transistor 144b and fixed current source 13. Coupling-wise, the gate, drain and source of each NMOS transistor 124b, 134b and 144b correspond to the base, collector and emitter of the counterpart NPN transistor 124a, 134a or 144a in FIG. 1A.

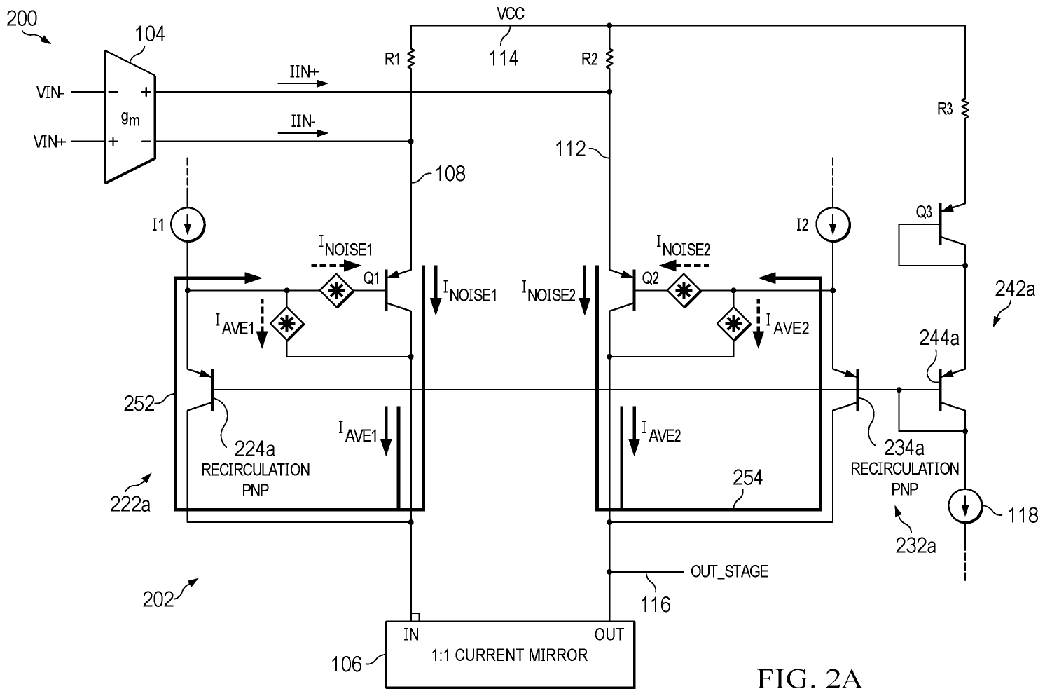

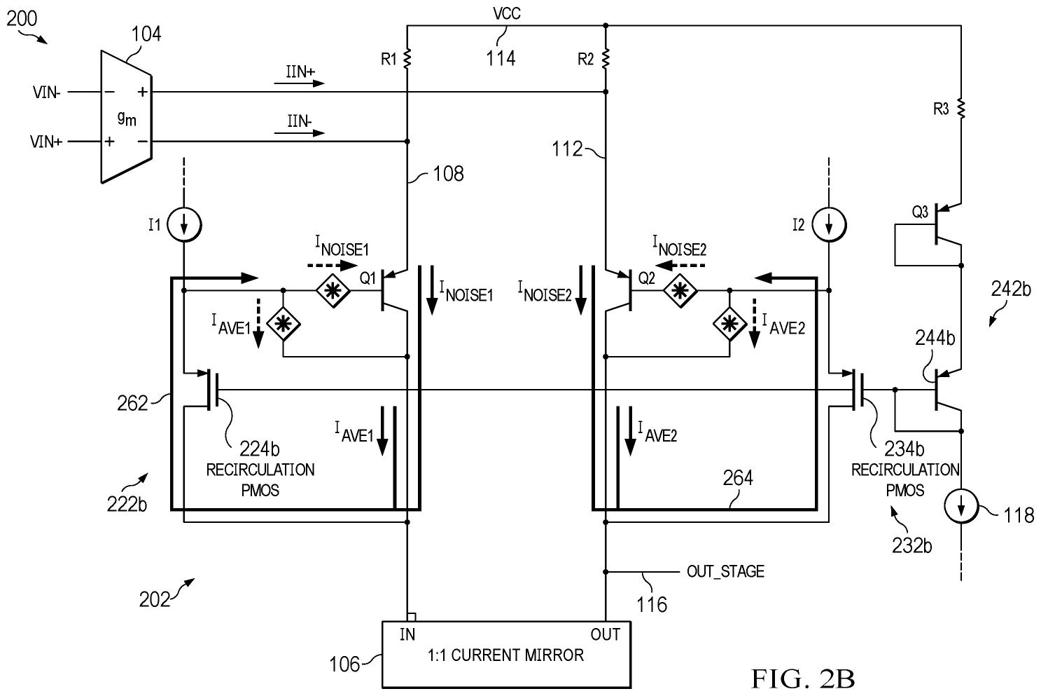

Thus, in operation, with biasing circuitry 142b activated, first recirculation circuitry 122b creates a first recirculation path 162 to isolate error currents I_{NOISE1} and I_{AVE1} produced by signal-conveyance BJT Q1. Second recirculation circuitry 132b operates similarly in that it creates a second recirculation path 164 to isolate error currents I_{NOISE2} and I_{AVE2} produced by signal-conveyance BJT Q2.

Whereas FIGS. 1A and 1B show configurations in which error currents are recirculated to the emitter nodes of BJTs Q1 and Q2 using NPN and NMOS transistors, respectively, FIGS. 2A and 2B show configurations in which error currents are recirculated to the collector nodes of Q1 and Q2, using p-type BJTs and p-type MOSFETs (i.e., PNP and PMOS transistors), respectively.

Stage 202 of amplifier 200 of FIG. 2A, which is directed to the PNP implementation of collector node recirculation, has a core that is substantially the same as that of FIG. 1A. The core of stage 202 includes the pair of signal-conveyance BJTs Q1 and Q2, voltage-to-current (VI) converter 104, the additional BJT Q3, current mirror 106, resistors R1, R2 and R3, and fixed current source 118. The core of stage 202 also includes branches 108 and 112, supply voltage terminal 114, and output node 116. In FIG. 2A, however, fixed current source 118 is indirectly coupled to the collector of transistor Q3 via PNP transistor 244a, which cooperates with fixed current source 118 to bias the recirculation circuitry of stage 202 to reduce error currents produced by Q1 and Q2.

The recirculation circuitry of stage 202 includes first and second recirculation circuitry 222a and 232a. First recirculation circuitry 222a includes a first recirculation PNP transistor 224a and a first fixed current source I1 coupled to the emitter of PNP transistor 224a and to the base of Q1. The collector of PNP transistor 224a is coupled to the collector of Q1. Second recirculation circuitry 232a includes a second recirculation PNP transistor 234a and a second fixed current source 12 coupled to the emitter of PNP transistor 234a and to the base of Q2. The collector of PNP transistor 234a is coupled to the collector of Q2. Biasing circuitry 242a includes PNP transistor 244a, the base and collector of which are coupled together and are also coupled to the bases of first and second recirculation PNP transistors 224a and 234a. The common base-collector node of PNP transistor 244a is coupled to fixed current source 118, and together they operate to bias first and second recirculation PNP transistors 224a and 234a.

In operation, first recirculation circuitry 222a creates a first recirculation path 252 to isolate error currents I_{NOISE1} and I_{AVE1} produced by Q1. Second recirculation circuitry 232a operates similarly in that it creates a second recirculation path 254 to isolate error currents I_{NOISE2} and I_{AVE2} produced by Q2.

In FIG. 2B, the core of stage 202 is the same as that in FIG. 2A, and thus core components are identified by the same reference numerals/symbols used in FIG. 2A. However, in FIG. 2B, the recirculation and biasing circuitry for stage (or portion) 202 of example amplifier 200, and in particular signal-conveying BJTs Q1 and Q2, is implemented with p-type MOSFETs (PMOS transistors), instead of PNP transistors. In FIG. 2B, the first and second recirculation circuitry are identified by reference numerals 222b and 232b, respectively, and the biasing circuitry is identified by reference numeral 242b. First recirculation circuitry 222b includes first recirculation PMOS transistor 224b and fixed current source I1, second recirculation circuitry 232b includes second recirculation PMOS transistor 234b and fixed current source 12, and biasing circuitry 242b includes PMOS transistor 244b and operates in cooperation with fixed current source 118. Coupling-wise, the gate, drain and source of each PMOS transistor 224b, 234b and 244b correspond to the base, collector and emitter of the counterpart PNP transistor in FIG. 2A.

In operation, first recirculation circuitry 222b creates a first recirculation path 262 to isolate error currents I_{NOISE1} and I_{AVE1} of Q1. Second recirculation circuitry 232b operates similarly in that it creates a second recirculation path 264 to isolate error currents I_{NOISE2} and I_{AVE2} of Q2.

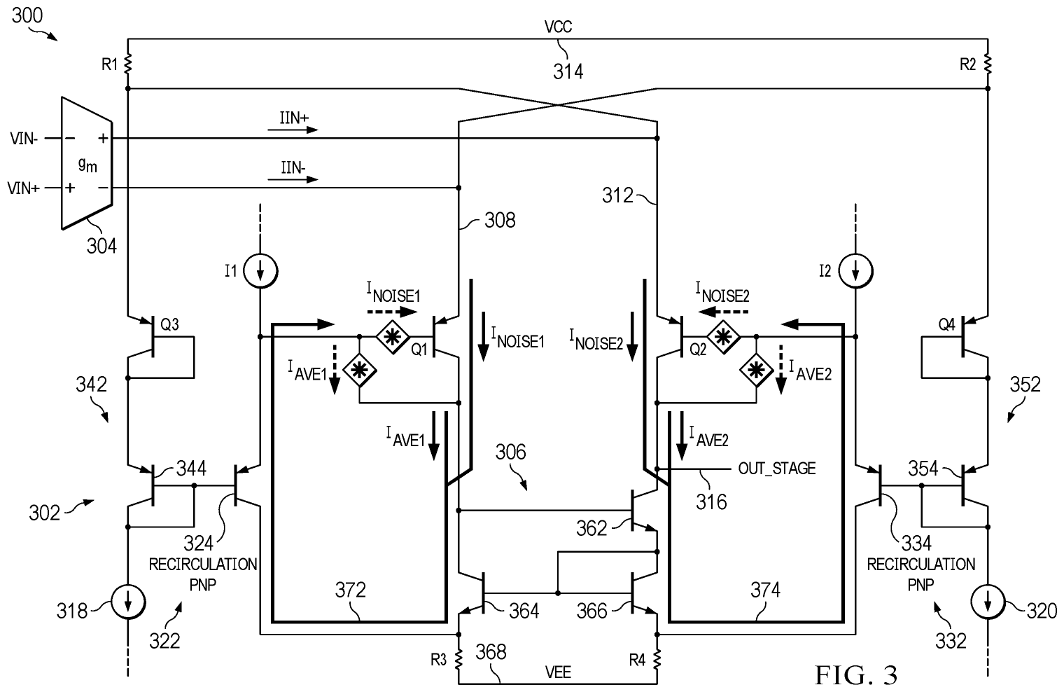

FIG. 3 is a circuit diagram of a stage (or portion) 302 of an example amplifier 300. The core of stage 302 has several of the same elements as the core of stage 102/202. Stage 302, however, has a cross-coupled architecture, as well as additional elements, some of which are used to implement the current mirror of stage 302.

The core of stage 302 includes a pair of signal-conveyance BJTs Q1 and Q2, a voltage-to-current (VI) converter 304, two additional BJTs Q3 and Q4, a current mirror 306 as an active load, fixed current sources 318 and 320, and resistors R1, R2, R3 and R4. The input/output ratio of the currents of current mirror 306 may be any suitable ratio, e.g., 1:1. Resistors R1 and R2 generally correspond to resistors R1 and R2 in the FIGS. 1A, 1B, 2A and 2B. The respective resistances of these resistors may vary depending on the application.

One end of each of R1 and R2 is coupled to a supply voltage terminal 314. The other end of R1 is coupled to the emitters of Q2 and Q3, while the other end of R2 is coupled to the emitters of Q1 and Q4. The collectors of Q1 and Q2 are coupled to current mirror 306. Each of Q3 and Q4 is configured such that its base and collector are coupled together.

VI converter 304 operates as does VI converter 104. The output of VI converter 304 from which current component IN− flows is coupled to a first branch 308 extending to the emitter of Q1, and the output of VI converter 304 from which current component IN+ flows is coupled to a second branch 312 extending to the emitter of Q2. Thus, VI converter 304 is configured to deliver current to Q1 and Q2. The collector of Q2 forms output node 316 of stage 302.

First and second recirculation circuitry 322 and 332 is provided for Q1 and Q2, respectively. First recirculation circuitry 322 includes a first recirculation PNP transistor 324 and a fixed current source I1 coupled to the emitter of transistor 324. Second recirculation circuitry 332 includes a second recirculation PNP transistor 334 and a fixed current source 12 coupled to the emitter of transistor 334.

In the cross-coupled architecture implementation of FIG. 3, separate biasing circuitry is provided for each instance of recirculation circuitry. To that end, first biasing circuitry 342 is associated with first recirculation circuitry 322, and second biasing circuitry 352 is associated with second recirculation circuitry 332. First biasing circuitry 342 includes a first biasing PMOS transistor 344 having an emitter coupled to the common collector-base node of Q3. The collector and base of first biasing PMOS transistor 344 are coupled together and also coupled to the base of first recirculation PMOS transistor 324 and to fixed current source 318. Second biasing circuitry 352 includes a second biasing PMOS transistor 354 having an emitter coupled to the common collector-base node of Q4. The collector and base of second biasing PMOS transistor 354 are coupled together and also coupled to the base of second recirculation PMOS transistor 334 and to fixed current source 320.

Current mirror 306 includes three NPN transistors 362, 364 and 366, as well as two resistors R3 and R4. The collector of transistor 362 is coupled to the collector of Q2 (i.e., at output 316), and the base of transistor 362 is coupled to the collectors of Q1 and transistor 364. The base of transistor 364 is coupled to the common base-collector node of transistor 366 and to the emitter of NPN transistor 362. The emitters of transistors 364 and 366 are coupled to another supply voltage terminal 368 through resistors R3 and R4, respectively. Supply voltage terminal 368 is adapted to be coupled to a second, e.g., negative supply voltage (VEE). The resistances of R3 and R4 may be set based on the desired current input/output ratio of current mirror 306.

In the cross-coupled architecture of FIG. 3, low bias currents are used as a starting point to minimize 1/f noise from current mirror transistors 362, 364 and 366, which do not have error-current-cancelation (e.g., recirculation) circuitry. PNP transistors are used in recirculation circuitry 322 and 332, rather than NPN transistors, to minimize the number of fixed bias currents needed with this architecture. Here, the error currents produced by Q1 and Q2 are recirculated through degeneration nodes of current mirror 306, which is an active load of stage 302. Error currents I_{NOISE1} and I_{AVE1} produced by Q1 are recirculated through path 372, which extends through current mirror transistor 364 and recirculation transistor 324. Error currents I_{NOISE2} and I_{AVE2} produced by Q2 are recirculated through path 374, which extends through current mirror transistors 362 and 366, as well as recirculation transistor 334. Canceling the error currents at degeneration nodes of current mirror 306, rather than at the collectors of Q1 and Q2, allows close to fixed collector-emitter voltages for recirculation transistors 324 and 334. This minimizes mismatch and modulation of their own avalanche currents with stage output voltage swing, which could otherwise introduce signal error.

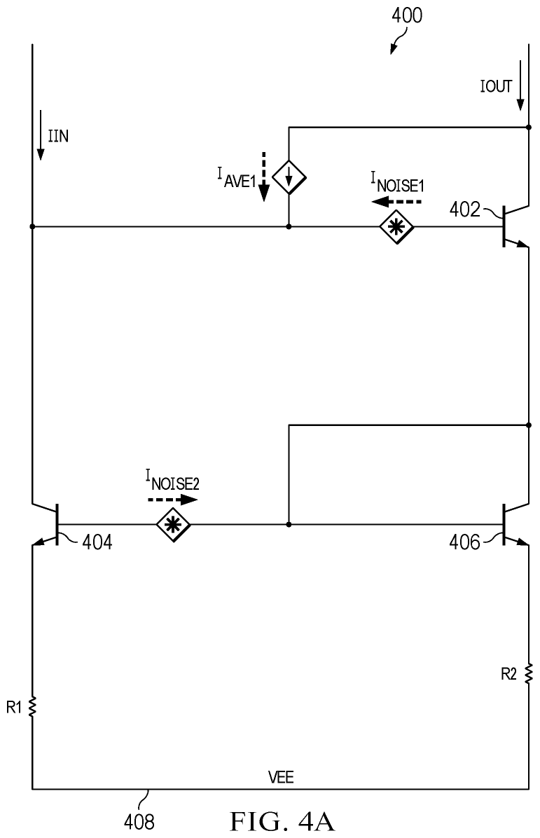

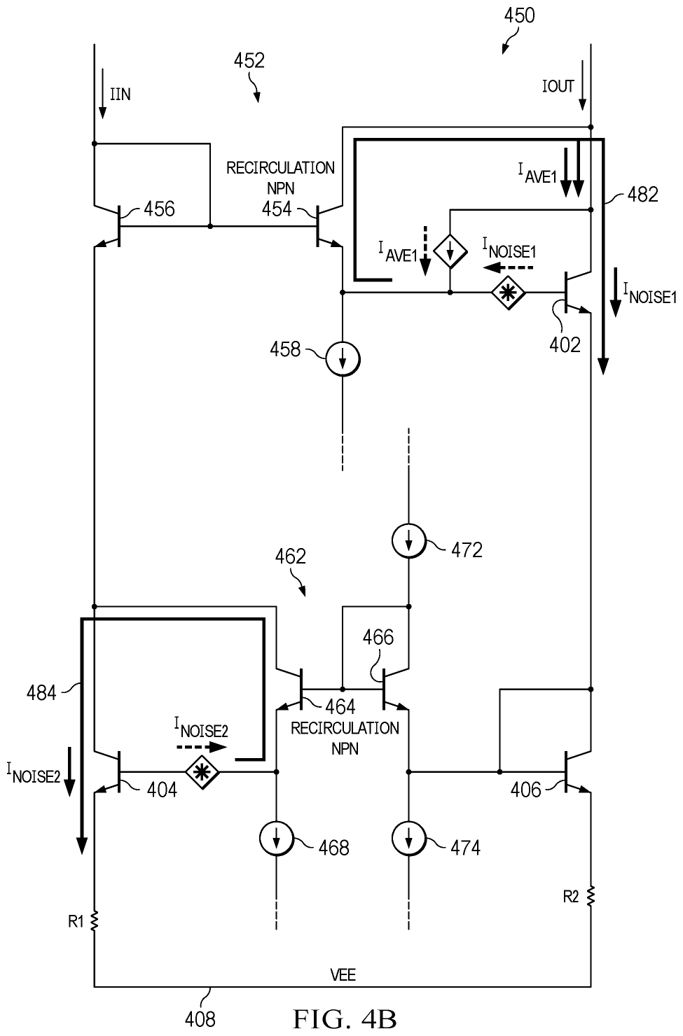

FIG. 4A is a circuit diagram of a Wilson current mirror 400, which is a type of current mirror that is able to achieve both base-current compensation and increased output resistance. However, Wilson current mirror 400 contains NPN transistors 402 and 404 that produce error currents. Each of those transistors produces a 1/f noise current (I_{NOISE1} and I_{NOISE2}), and transistor 402 also produces an avalanche current (I_{AVE1}).

Wilson current mirror 400 also includes NPN transistor 406, and all three of the NPN transistors may be matched. IIN may represent a reference current and IOUT may represent the output current of current mirror 400.

Structurally, the input and output of Wilson current mirror 400 are coupled to the collectors of transistors 404 and 402, respectively. The input is also coupled to the base of transistor 402. The base and collector of transistor 406 are coupled together, which common node is also coupled to the emitter of transistor 402 and the base of transistor 404. The emitters of transistors 404 and 406 are coupled to a voltage supply terminal 408 through resistors R1 and R2, respectively. Voltage supply terminal 408 is adapted to be coupled to a voltage supply (e.g., VEE).

To reduce or cancel the error currents produced by transistors 402 and 404, Wilson current mirror 400 may be modified to include error-compensation circuitry. FIG. 4B is a circuit diagram of a Wilson current mirror incorporating error-current compensation circuitry 450.

In FIG. 4B, first recirculation and biasing circuitry 452 is incorporated to reduce or cancel I_{NOISE1} and I_{AVE1} produced by transistor 402, and second recirculation and biasing circuitry 462 is incorporated to reduce or cancel I_{NOISE2} produced by transistor 404. First recirculation and biasing circuitry 452 includes a first recirculation NPN transistor 454, a first biasing transistor 456, and fixed current source 458. Second recirculation and biasing circuitry 462 includes a second recirculation NPN transistor 464, a second biasing transistor 466, and fixed current sources 468, 472 and 474.

First recirculation NPN transistor 454 is coupled with respect to transistor 402, such that when biased, transistor 454 forms a first recirculation path 482. Second recirculation NPN transistor 464 is coupled with respect to transistor 404 to form a second recirculation path 484 when transistor 464 is biased.

Current mirror 450 may be used in place of current mirror 306 in the cross-coupled architecture shown in FIG. 3 to further lessen the impact of 1/f noise and avalanche currents on the output signal. Possible tradeoffs in doing so include higher flat band noise, DC error due to branch base current contribution mismatch, and increased phase delay in the current mirror's local feedback loop.

In each of the preceding examples, the recirculation transistors have their own error currents that can produce signal errors. To achieve an overall reduction in signal errors, the signal errors produced by each recirculation transistor must be smaller than the signal errors the recirculation transistor is used to cancel. This is achieved, in part, by biasing recirculation transistors with small currents to minimize their noise contributions and making recirculation BJTs small to minimize their weak avalanche current error contributions.

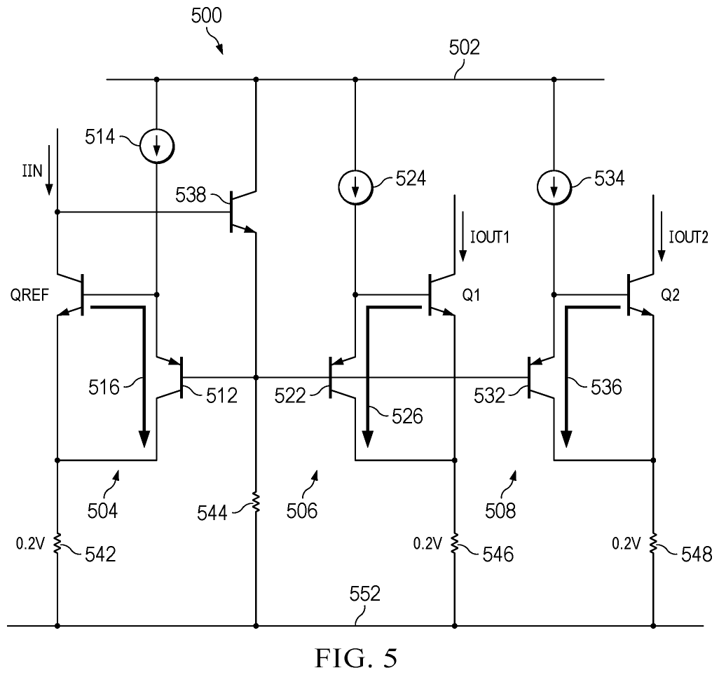

FIG. 5 is a circuit diagram of an example current mirror 500 with example recirculation circuitry. Current mirror 500 includes two core NPN transistors Q1 and Q2, and a reference NPN transistor QREF, the collector of which is a current input terminal to receive a reference current IIN. The collectors of Q1 and Q2 are output current terminals for output currents IOUT1 and IOUT2. Current mirror 500 further includes three instances of recirculation circuitry 504, 506 and 508 for QREF, Q1 and Q2, respectively.

Recirculation circuitry 504 includes a recirculation PNP transistor 512 and a fixed current source 514 coupled between supply voltage terminal 502 and the emitter of transistor 512. The base of QREF is coupled to the emitter of recirculation PNP transistor 512, and the collector of transistor 512 is coupled to the emitter of QREF to form recirculation path 516.

Recirculation circuitry 506 includes a recirculation PNP transistor 522 and a fixed current source 524 coupled between supply voltage terminal 502 and the emitter of transistor 522. The base of Q1 is coupled to the emitter of recirculation PNP transistor 522, and the collector of transistor 522 is coupled to the emitter of Q1 to form recirculation path 526.

Recirculation circuitry 508 includes a recirculation PNP transistor 532 and a fixed current source 534 coupled between supply voltage terminal 502 and the emitter of transistor 532. The base of Q2 is coupled to the emitter of recirculation PNP transistor 532, and the collector of transistor 532 is coupled to the emitter of Q2 to form recirculation path 536.

Current mirror 500 further includes a transistor 538, which is an NPN transistor in which its collector is coupled to supply voltage terminal 502, its base is coupled to the collector of QREF, and its emitter is coupled to the bases of PNP recirculation transistors 512, 522 and 532.

First ends of resistors 542, 544, 546 and 548 are coupled to the emitters of QREF, transistor 538, Q1 and Q2, respectively, as shown in FIG. 5. The second end of each of resistors 542, 544, 546 and 548 is coupled to a common node 552, which may be ground. In operation, the voltage drop across each of resistors 542, 546 and 548 is approximately 0.2 V. The resistances of resistors 542, 546 and 548 may be set accordingly. The resistance of resistor 544 is independent of the voltage drops across resistors 542, 546 and 548.

Recirculation paths 516, 526 and 536 function to isolate and reduce or cancel error current(s), e.g., 1/f noise current and/or weak avalanche breakdown current, produced by QREF, Q1 and Q2, respectively.

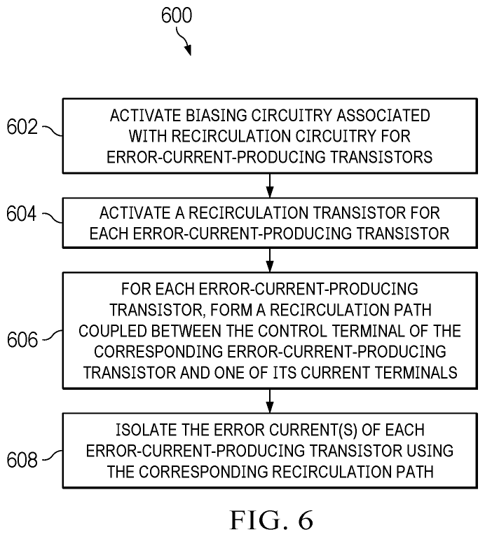

FIG. 6 is a flow diagram of an example method 600 of operating recirculation circuitry with respect to error-current-producing transistors, such as signal-conveyance transistors in an amplifier stage. In operation 602, biasing circuitry associated with the recirculation circuitry is activated. Each instance of recirculation circuitry may have its own biasing circuitry, or the same biasing circuitry may be used for more than one instance of recirculation circuitry. In operation 604, for each error-current-producing transistor, the biasing circuitry activates an associated recirculation transistor. In operation 606, a recirculation path is formed for each error-current-producing transistor. Each path is coupled between the control terminal of the corresponding error-current-producing transistor and one of its current terminals. With the recirculation path(s) formed, in operation 608, the error current(s) of each error-current-producing transistor is isolated using the corresponding recirculation path. The error currents may include a 1/f noise current and/or a weak breakdown avalanche current.

FIG. 6 depicts one possible order of operations. Not all operations need necessarily be performed in the order described. Some operations may be combined into a single operation. Additional operations and/or alternative operations may be performed.

Various examples of recirculation and biasing circuitry are provided for eliminating or reducing 1/f noise and weak avalanche breakdown currents produced by BJTs. Such circuitry may be incorporated into amplifier stages of various configurations to target specific BJTs, e.g., signal-conveyance BJTs, to eliminate or reduce the effects of their error currents on the output signal.

Targeted cancellation is highly effective at reducing overall 1/f noise introduced to the signal because noise is often dominated by contributions from a small number of BJTs. Solutions provided herein allow large bias currents that facilitate high-speed performance (i.e., high bandwidth, high slew rate, low flat-band noise) to be used while also achieving low 1/f noise. This, in turn, facilitates high performance over a wide bandwidth. Solutions provided herein eliminate the effects of weak avalanche breakdown current from targeted BJTs on the signal. Targeted cancellation is highly effective at reducing overall avalanche current error in the signal since it is often dominated by contributions from a small number of BJTs that experience a large portion of the supply voltage across their collector-base junctions. Solutions provided herein allow large supply voltages to be used without the need for cascode transistors. This facilitates a large output voltage signal dynamic range.

Solutions provided herein have a wide range of applications in amplifiers having bipolar signal transistors that require support for high supply voltages with excellent distortion performance and high DC precision, and/or require excellent low-frequency noise performance.

In an amplifier stage with a cross-coupled architecture, such as that shown in FIG. 3, the recirculation and biasing circuitry may reduce input-referred voltage noise significantly, particularly at lower frequencies. Such circuitry may also reduce 2^{nd}-order harmonic distortion at frequencies greater than approximately 100 kHz.

The term “couple” is used throughout the specification. The term and derivatives thereof may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

A device that is “configured to” perform a task or function may be configured (i.e. programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal” and “node” may be an interconnection, lead and/or pin. Unless specifically stated to the contrary, these terms generally mean an interconnection between or a terminus of a device element, a circuit element, an integrated circuit, a device or other electronic or semiconductor component. The term “control terminal” as used herein refers to the base of an associated BJT and to the gate of an associated MOSFET. The term “current terminal” refers to a collector or emitter of a BJT and to a drain or source of a MOSFET.

A circuit or device that is described herein as including certain components may instead be adapted to be coupled to those components to form the described circuitry or device. For example, a structure described as including one or more semiconductor elements (such as transistors), one or more passive elements (such as resistors), and/or one or more sources (such as voltage and/or current sources) may instead include only the semiconductor elements within a single physical device (i.e. a semiconductor die and/or integrated circuit (IC) package) and may be adapted to be coupled to at least some of the passive elements and/or the sources to form the described structure either at a time of manufacture or after a time of manufacture, for example, by an end-user and/or a third-party. Circuits described herein are reconfigurable to include the replaced components to provide functionality at least partially similar to functionality available prior to the component replacement.

Resistance values of various resistors described herein may vary depending on the particular application of the circuit. The supply voltage(s), e.g., VCC and VEE, of the various circuits described herein may any suitable voltage for the particular application. The current delivered by any of the current sources described herein may be set based on the particular function to be performed. Unless otherwise stated, “about,” “approximately,” or “substantially” preceding a value means+/−10 percent of the stated value.

Modifications of the described examples are possible, as are other examples, within the scope of the claims. Moreover, features described herein may be applied in other environments and applications consistent with the teachings provided.

What is claimed is:

1. A circuit comprising:
a target bipolar junction transistor (BJT) having an emitter, a collector and a base; and
recirculation circuitry coupled to the base of the target BJT and to one of the collector or the emitter of the target BJT, the recirculation circuitry configured to form a recirculation path for at least one error current produced by the target BJT.

2. The circuit of claim 1, wherein the recirculation circuitry includes a recirculation transistor and a fixed current source coupled to the recirculation transistor.

3. The circuit of claim 2, wherein the recirculation transistor has a first current terminal coupled to the base of the target BJT and a second current terminal coupled to one of the collector or the emitter of the target BJT.

4. The circuit of claim 3, further comprising:
biasing circuitry coupled to a control terminal of the recirculation transistor.

5. The circuit of claim 3, wherein the recirculation transistor is an n-type BJT, the first current terminal of which is an emitter that is coupled to the base of the target BJT and to the fixed current source, and the second current terminal of which is a collector that is coupled to the emitter of the target BJT.

6. The circuit of claim 3, wherein the recirculation transistor is an n-type metal-oxide-silicon field-effect transistor, the first current terminal of which is a source that is coupled to the base of the target BJT and to the fixed current source, and the second current terminal of which is a drain that is coupled to the emitter of the target BJT.

7. The circuit of claim 3, wherein the recirculation transistor is a p-type BJT, the first current terminal of which is an emitter that is coupled to the base of the target BJT and to the fixed current source, and the second current terminal of which is a collector that is coupled to the collector of the target BJT.

8. The circuit of claim 3, wherein the recirculation transistor is a p-type metal-oxide-silicon field-effect transistor, the first current terminal of which is a source that is coupled to the base of the target BJT and to the fixed current source, and the second current terminal of which is a drain that is coupled to the collector of the target BJT.

9. The circuit of claim 3, further comprising:
a current mirror including a first transistor coupled to the collector of the target BJT and a second transistor coupled to the first transistor,
wherein the recirculation transistor is a p-type BJT, the first current terminal of which is an emitter that is coupled to the base of the target BJT and to the fixed current source, and the second current terminal of which is a collector that is coupled to the first transistor of the mirror.

10. The circuit of claim 9, wherein the recirculation path extends through the target BJT, the first transistor of the current mirror, and the recirculation transistor.

11. The circuit of claim 9, wherein the recirculation path extends through the target BJT, the first and second transistors of the current mirror, and the recirculation transistor.

12. The circuit of claim 3, wherein the recirculation transistor is an n-type BJT, the first current terminal of which is an emitter that is coupled to the base of the target BJT and to the fixed current source, and the second current terminal of which is a collector that is coupled to the collector of the target BJT.

13. The circuit of claim 3, wherein the recirculation transistor is a p-type BJT, the first current terminal of which is an emitter that is coupled to the base of the target BJT and to the fixed current source, and the second current terminal of which is a collector that is coupled to the emitter of the target BJT.

14. An amplifier comprising:
first and second signal-conveyance bipolar junction transistors (BJTs), each having an emitter, a collector and a base;
a first branch coupled to the emitter of the first signal-conveyance BJT and to a first input current path;
a second branch coupled to the emitter of the second signal-conveyance BJT and to a second input current path;
first recirculation circuitry coupled to the base of the first signal-conveyance BJT and to one of the collector or the emitter of the first signal-conveyance BJT;
second recirculation circuitry coupled to the base of the second signal-conveyance BJT and to one of the collector or the emitter of the second signal-conveyance BJT; and
biasing circuitry coupled to the first and second recirculation circuitry.

15. The amplifier of claim 14, wherein:
the first recirculation circuitry includes a first recirculation transistor and a first fixed current source coupled to the first recirculation transistor; and
the second recirculation circuitry includes a second recirculation transistor and a second fixed current source coupled to the second recirculation transistor.

16. The amplifier of claim 14, further comprising:
a current mirror coupled to the collector of each of the first and second signal-conveyance BJTs.

17. The amplifier of claim 15, wherein:
the first recirculation circuitry is configured to form a first recirculation path for at least one error current produced by the first signal-conveyance BJT; and
the second recirculation is configured to form a second recirculation path for at least one error current produced by the second signal-conveyance BJT.

18. The amplifier of claim 17, wherein:
the first recirculation path extends through the first signal-conveyance BJT, through the first recirculation transistor, and to the base of the first signal-conveyance BJT; and
the second recirculation path extends through the second signal conveyance BJT, through the second recirculation transistor, and to the base of the second signal-conveyance BJT.

19. An amplifier comprising:
n target bipolar junction transistors (BJTs), each having an emitter, a collector and a base; and
n instances of recirculation circuitry, each coupled to the base of a corresponding target BJT and to one of the collector or the emitter of the corresponding target BJT, each of the n instances of recirculation circuitry including a recirculation transistor; and
biasing circuitry coupled to the n instances of recirculation circuitry, the biasing circuitry configured to activate the n recirculation transistors to form n recirculation paths for the n target BJTs, respectively, to isolate at least one error current produced by each of the n target BJTs.

20. The amplifier of claim 19, wherein each of the n recirculation paths is coupled between the base of the corresponding target BJT and one of the collector or emitter of the corresponding target BJT.

21. The amplifier of claim 20, wherein each of the n recirculation paths extends through the corresponding recirculation transistor.
